(19) United States
(12) Patent Application Publication
(10) Pub. No.: US 2005/0102115 A1
(43) Pub. Date: May 12, 2005

(54) Digital oscilloscope with customizable display for selected function options

(76) Inventors: Gary J. Waldo, Hillsboro, OR (US); Frank H. Goovaerts, Banks, OR (US); Tristan A. Robinson, Beaverton, OR (US)

Correspondence Address: Thomas F. Lenihan;Tektronix, Inc., M/S 50-LAW, P.O. Box 500, Beaverton, OR, 97077-0001, US

(21) Appl. No.: 10/980,001

(22) Filed: Nov. 2, 2004

Related U.S. Application Data
(60) Provisional application No. 60/518,528, filed on Nov. 7, 2003.

(51) Int. Cl. G06F 19/00; G01R 13/02; G09G 5/00

(52) U.S. Cl. 702/68; 702/67; 702/66; 345/208

(57) ABSTRACT

A Digital Oscilloscope has an information storage facility, a processor connected to the storage facility and having a data input, and a graphical display connected to the processor. The storage facility contains a multitude of functional tools for processing a signal from the input and for displaying a result on the display. The display has a control portion operable to display a selected limited subset of the tools. A limited subset of tools are selected from among the multitude of tools, and are displayed on a control portion of the display. The selection may be made manually by the user, or may be made automatically based on the user's recorded use of tools. Multiple subsets may be stored to enable different users to share the oscilloscope.

### CLAIM FOR PRIORITY

The subject patent application claims priority from U.S. Provisional Patent Application Ser. No. 60/518,528, entitled, CUSTOMIZABLE HALF-SCREEN CONTROL WINDOW FOR A TEST AND MEASUREMENT INSTRUMENT, (Waldo, et al.), filed 07 Nov. 2003.

### FIELD OF THE INVENTION

This invention relates to digital oscilloscopes, and more particularly to the configuration of display elements of digital oscilloscopes.

### BACKGROUND OF THE INVENTION

Digital Storage Oscilloscopes (DSOs) are powerful useful instruments for analysis of electronic equipment and devices. Their versatility gives them a wide range of capabilities and functions that make them useful for many tasks. A DSO may have hundreds of different functional capabilities or “tools”, so that users with widely different needs may find tools and capabilities that fulfill those needs. However, as the range of functions increases, the complexity of the instrument may increase to make operation more daunting, especially to an inexperienced or occasional user, or one with simpler needs. Simply to access all the possible functions can require a menu of such complexity that certain desired functions may not be readily located by a user.

The disadvantages of complex menus needed to access a multitude of different functions or “tools” of a DSO is exacerbated by the fact that different DSO manufacturers may employ different menu structures, so that even a user who has mastered part or all of the menu of a given manufacturer may face difficulties when operating a DSO of a different manufacturer. Moreover, even a user who is operating a DSO whose menu structure he has mastered is slowed or handicapped by the complexity of the menu. The user may normally employ only a few of the tools available, and these may be at familiar menu locations. However, given complex menu trees, it requires unwanted time and effort to work through the menu to find a tool, and for each switch to or selection of a different tool. The presence of many tools that are not of use to a given user is generally seen as unwanted “clutter.” Efforts to make menus “deep”, with fewer selections at any point, but more levels of sub-selections may provide some apparent simplicity by reducing the number of choices at any point. However, deeply located items may be lost, with the user unable to locate them. On the other hand, shallower menus with fewer levels but more choices at each level may be perceived by some users as overly complex or confusing.

### SUMMARY OF THE INVENTION

The present invention overcomes the limitations of the prior art by providing an interactive menu for a Digital Oscilloscope. The oscilloscope has an information storage facility, a processor connected to the storage facility and having a data input, and a graphical display connected to the processor. The storage facility contains a multitude of functional tools for processing a signal from the input and for displaying a result on the display. The display has a control portion operable to display a selected limited subset of the tools. A limited subset of tools are selected from among the multitude of tools, and are displayed on a control portion of the display. The selection may be made manually by the user, or may be made automatically based on the user's recorded use of tools. Multiple subsets may be stored to enable different users to share the oscilloscope.

### BRIEF DESCRIPTION OF THE DRAWINGS

FIG. 1 shows a simplified illustration of an oscilloscope according to a preferred embodiment of the invention

FIG. 2 shows a sample operational display screen image from an oscilloscope operating according to a preferred embodiment of the invention.

FIG. 3 shows sample setup display screen image from an oscilloscope operating according to a preferred embodiment of the invention.

### DETAILED DESCRIPTION OF A PREFERRED EMBODIMENT

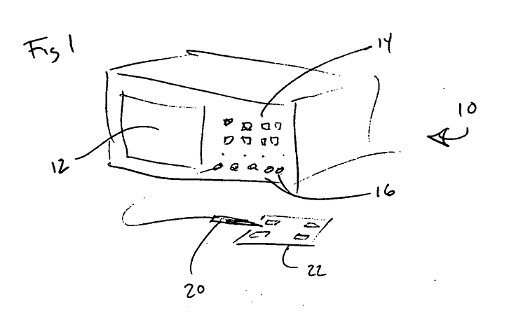

FIG. 1 shows a Digital Storage Oscilloscope (DSO) or digital phosphor oscilloscope 10 having a display screen 12, an array of controls 14, and a set of input connectors 16. The DSO includes internal processor circuitry (not shown) connected to the input for receiving a signal, and to the display for displaying the processed signal. The DSO includes internal memory for storing data, masks, and for storing operational software that provides tool modules for processing signals in various useful ways. The DSO includes a probe 20 connected to an input 16, and operable for making electrical contact with a device 22 under test. Other uses may employ cables connected directly from a cable connector on a device under test to the input 16.

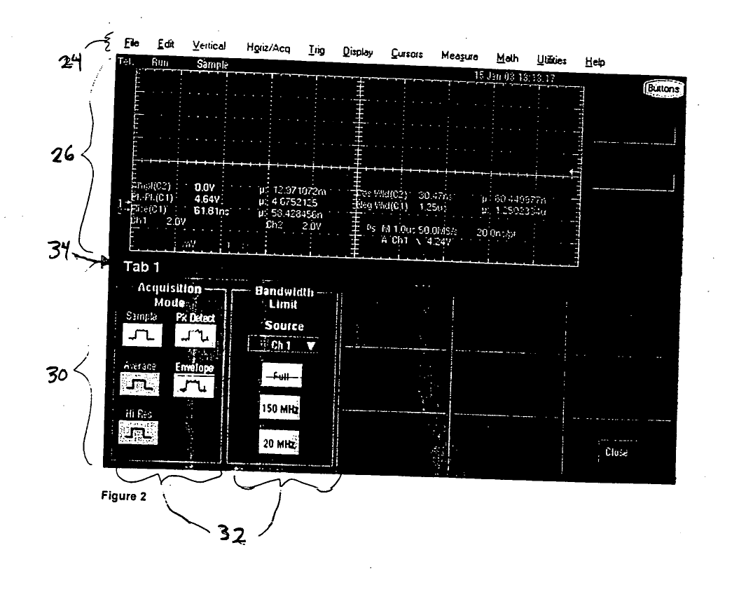

FIG. 2 shows a customized DSO graphical user interface as displayed on the display screen 12. The interface includes a menu bar 24 at the upper margin of the screen, a signal display portion 26 occupying a major upper portion of the screen, and a control portion 30 occupying the remaining lower portion of the screen. The menu bar has several indicated categories in the manner of a Windows interface, each category having an associated drop-down menu of sub categories or commands. The commands may be linked to additional sub commands. Each command is linked to one of the multitude of tool modules or other programmed functions stored in the DSO's memory. Thus, a user may access any operating mode or function by working through the menu structure.

To avoid working through the menu structure each time a different tool is desired, the control portion of the display has space for the continuous display of several tool blocks 32 selected by the user in the manner discussed below. Each tool block may have interface buttons that allow customization or operation of the tool functions, in the manner of a set of buttons or controls on a traditional oscilloscope. The tools are arranged on pages, each having a tab 34 at the upper margin of the control portion. To provide rapid access to different pages, the tabs of all pages remain visible even when another page is displayed based on the user's selection of that page's tab. The use of tabbed pages enables the tools to be arranged in a logical manner, so that tools associated with a common task are displayed at the same time, and a user does not need to switch between pages during a typical task.

When switching tasks, the user may switch to another tabbed page with tools selected for appropriateness to that task. The tabs are customizable with labels selected to relate to the particular task.

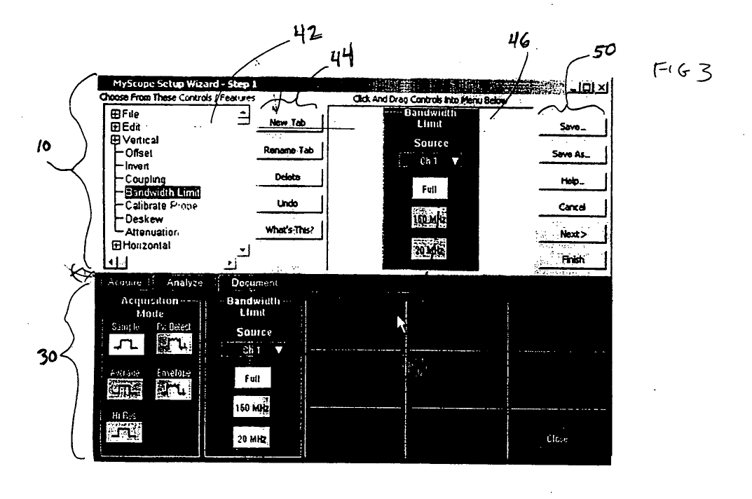

FIG. 3 illustrates the process by which a user generates a custom interface as described above. The user has employed the menu bar to select a command initiating the creation of a new custom interface. This opens a setup window 10 in the upper portion of the screen above the control portion 30. The setup window has a command selection window 42 that has a listing of the elements and commands of the original menu bar, with the subcommands available upon selection in an expanding tree format. This allows the user to access the same tools and functions as in the menu bar, but for the purpose of selecting them for inclusion in a custom interface layout. To the right of the selection window are a set of tab buttons 44 allowing the user to create and edit tabs for new and existing tabbed pages. The buttons allow a new tab to be created, an existing tab to be renamed, a tab to be deleted, an action to be undone, and the access to a help facility.

To the right of the tab buttons, a preview window 46 serves to display a tool that has been selected in the command selection window. This shows the user how the tool would appear if selected. To the right of the preview window, a set of command buttons 50 provides the user with command options to save a custom interface, access help, cancel a creation or editing session, proceed to the next step, or finish a creation or editing session.

When the user has opened the setup window, the user begins by establishing a first tab. In the default, a single tab labeled “tab 1” is provided. The user then clicks the “rename tab” button and is offered a dialog box in which the desired tab name (in this example: “Acquire”) is typed. The user then selects which commands or tools are desired for this tabbed page from the command selection window. The user selects a menu item, which expands to list the available tools. A tool is selected, and displayed in the preview window. If the user is satisfied with the tool, he drags it to a desired location on the control portion 30 of the display.

The tool may be modified by the user while displayed in the preview window. To modify the tool, an element is selected, and a dialog box opens to allow the user to enter revised parameters for that aspect of the tool. For instance, the “Bandwidth Limit” tool illustrated in the preview window may be modified to change the source channel, and the bandwidth frequency limits. This calls up a listing of options that may be selected. In the preferred embodiment, for simplicity of operation, the user cannot enter parameter values. The user's input is limited to selecting or de-selecting the individual components that make up that control. For example, the user can remove the 20 MHz setting from the Bandwidth control. In alternative embodiments, functionality to change parameters of tools may be provided where suitable. In an alternative embodiment, the tool may also be modified by clicking with a secondary mouse button (“right-clicking”) on an aspect of the previewed tool, or an aspect of a tool already dragged to the control portion of the display.

The user proceeds to select all tools desired for a given tabbed page, to add additional tabbed pages and to populate them with appropriate tools, until a compete custom interface is achieved. This is then saved, and stored in the DSO's memory. When the interface is completed, the setup window is closed, and the signal display portion of the window is restored for operation of the DSO.

Many different users may each generate and save one or more custom interface, depending on their needs. When a user begins a session with the DSO, he may recall from memory the desired interface, so that it is not necessary to rebuild it. The DSO may also include several pre-programmed interfaces created for typical needs of different types of anticipated uses and users. These may be named in a manner correlated with the task or type of user, or level of user expertise. These may also be accessed via a help tutorial in which the DSO responds to a “How do I . . . ?” help query from the user, by suggesting a particular custom interface. Such preexisting interfaces may be edited by users and saved under new names to allow some customization without requiring a new user to create an interface from scratch. The ability to save multiple alternative control interfaces provides several benefits. First, it reduces the perceived complexity of a powerful, feature-laden DSO by allowing a user to avoid the complexity of unused features after a control interface is generated. Second, it helps a user who only sporadically uses the DSO to quickly return to productive use months after last using the DSO, without the problems caused by forgetting where useful tools are located in a complex menu structure. Third, it allows instrument sharing without the need to compromise between the typical needs of different users. Fourth, it allows an engineer who needs to test multiple different device types a customized interface for each device type or task.

The DSO may also include context sensitive menu controls using the mouse scroll wheel features of Windows. When pointing the cursor at an area of interest anywhere on the display screen, a user can adjust parameter values with the scroll wheel on the mouse and to toggle between coarse and fine adjustments by pressing the mousewheel.

The advantages of the above custom-built interfaces may be extended to users who are not inclined to create custom interfaces, or who are unaware of the feature. As such users work with a DSO, their usage patterns and habits are recorded by the DSO, which employs a log-in function to identify which user is using the instrument. The DSO keeps a list of most frequently used tools, and these are the basis for a proposed automatically-generated custom interface. After a period of use, the DSO will acquire sufficient data to offer the user a custom interface.

The custom interface generated by the DSO may simply be a list of most frequently used tools, or it may be based on a more sophisticated algorithm that weighs the recency of use, and the level of actual activity of a tool while it is in use. The number of tools may be limited by the capacity of a single tabbed page, or may extend over several pages, allocated based on a logical arrangement of tools.

When recording use, the DSO may limit “in-use” time to time in which the system is actually active. After a limited time (e.g. 5 minutes) following the last use, the system “times out” so that tools displayed on an inactive DSO are not weighed in generating a proposed custom interface. A tool is considered “in use” when displayed on an actively operated DSO for a period extending for a selected interval (e.g. 2 hours) after that tool in particular is employed. Each time a tool is used, its “in use” designation is refreshed, extending the timer to two hours. After collecting the in-use data for an extended period, those functions with the greatest duration of “in-use” time are selected for inclusion in the custom menu. A threshold of use time may be employed to omit those functions that were only briefly used, even if there would be room to display them. This avoids the inclusion of a tool that was tried and rejected by a user. In addition to basing inclusion on duration of use, the total number of uses may also be factored into the determination.

In addition, the system may record and correlate when tools are used in conjunction with a set of other tools, so that such tools with correlating use may be included on a single tabbed page, while a set of other tools that tend to be used together may be included on another page. While the system may be set to offer a proposed tool menu after a selected number of hours of use, it may also offer such a menu based on a determination of when the user's use patterns have stabilized. For instance, when no more than 20% of tools used change in a 2 hour period of use, the system may offer the proposed menu.

The automatic facility may include other user- or system-controllable features. For instance, the user may place a limit on the number of tools to be displayed at one time, or may request a maximum number of controls on multiple pages, effectively recording the history of tool use. Normally, the system offers a custom menu when appropriate, and that menu is stored under a name selected by the user. It would then remain unchanged for the user. However, the system may also offer an ongoing updating mode whereby the menu is continually updated. Or, the system may record usage on an ongoing basis, and offer a new or modified menu of tools when use patterns have changed and stabilized. The user may disable and reactivate the feature, which can be useful if the user is beginning a new type of work, and wishes to keep a former custom menu, and to generate a new menu for the new type of project.

While the above is discussed in terms of preferred and alternative embodiments, the invention is not intended to be so limited.

1. A Digital Oscilloscope comprising:
an information storage facility;
a processor connected to the storage facility and having a data input;
a graphical display connected to the processor;
the storage facility containing a multitude of functional tools for processing a signal from the input and for displaying a result on the display;
the display having a control portion operable to display a selected limited subset of the tools; and;
selection means for selecting the limited subset from the multitude of tools.

2. The apparatus of claim 1 wherein the selection means includes a menu facility operable to display tool options to a user and to receive tool selection inputs from the user.

3. The apparatus of claim 2 wherein the menu facility includes means to display available tools, and to modify selected tools.

4. The apparatus of claim 2 wherein the display includes a menu bar listing tool options in a categorized format, and wherein the menu facility includes a listing of the tool options in the categorized format.

5. The apparatus of claim 4 wherein the menu facility is located on the display in an area other than the control portion, and wherein the selection means is operable to drag items from the displayed tool options to the control portion of the display.

6. The apparatus of claim 1 wherein the storage facility is operable to store the tool subset selected by a user, such that the subset may be later recalled by the user.

7. The apparatus of claim 6 wherein the storage facility is operable to store a plurality of different tool subsets.

8. The apparatus of claim 1 wherein the selection means includes automatic means for generating a selected subset of tools based on which tools are used.

9. The apparatus of claim 8 wherein the automatic means operates to record tool usage over a selected time interval.

10. The apparatus of claim 8 wherein the automatic means includes a facility for offering the user a subset of tools after a selected usage pattern is determined.

11. A method of operating a Digital Oscilloscope having an information storage facility, a processor, and a graphical display, the method comprising:
storing in the storage facility a multitude of functional tools for processing a signal from the input and for displaying a result on the display;
providing a selection means for selecting a limited subset of the tools; and
displaying the limited subset in a control portion of the display.

12. The method of claim 11 wherein the selection means includes displaying tool options to a user and receiving tool selection inputs from the user.

13. The method of claim 12 including to displaying available tools, providing a facility for the user to modify selected tools.

14. The method of claim 12 including displaying a menu bar listing tool options in a categorized format, and displaying a listing of the tool options in the categorized format.

15. The method of claim 14 including displaying the listing of tool options in a portion of the display other than the control portion, and enabling selection of tool options in response to a user dragging a tool option into the control area.

16. The method of claim 11 including storing the tool subset selected by a user, such that the subset may be later recalled by the user.

17. The method of claim 16 including storing a plurality of different tool subsets.

18. The method of claim 11 including automatically generating a selected subset of tools based on which tools are used.

19. The method of claim 18 including recording tool usage over a selected time interval.

20. The method of claim 18 including offering the user a subset of tools after a selected usage pattern is determined.
